(19) United States
(12) Patent Application Publication
(10) Pub. No.: US 2008/0054895 A1
(43) Pub. Date: Mar. 6, 2008

(54) MAGNETIC DETECTION DEVICE HAVING SECOND BRIDGE CIRCUIT INCLUDING FIXED RESISTANCE ELEMENT WITH HIGH RESISTANCE

(75) Inventors: Yoshito Sasaki, Niigata-ken (JP); Katsuya Kikuiri, Niigata-ken (JP); Kiyoshi Sato, Niigata-ken (JP)

Correspondence Address: BRINKS HOFER GILSON & LIONE, P.O. BOX 10395, CHICAGO, IL, 60610, US

(73) Assignee: ALPS ELECTRIC CO., LTD., Tokyo (JP)

(21) Appl. No.: 11/679,102

(22) Filed: Feb. 26, 2007

(30) Foreign Application Priority Data
Aug. 30, 2006 (JP) 2006-234389

(51) Int. Cl. G01B 7/30; G01R 33/02

(52) U.S. Cl. 324/252; 324/207.21

(57) ABSTRACT

A magnetic detection device capable of reducing current consumption includes a second series circuit connected in parallel to a first series circuit. The first series circuit includes a first magneto-resistance element, and a third series circuit 30 includes a second magneto-resistance element. The second series circuit includes fixed resistance elements. Electric resistance of the fixed resistance elements is larger than those of respective resistance elements included in a sensor unit, thereby reducing current consumption.

This application claims the benefit of Japanese Patent application No. 2006-234389 filed Aug. 30, 2006, the entire contents of which are incorporated herein by reference.

### BACKGROUND OF THE INVENTION

1. Field of the Invention

The present invention relates to a magnetic detection device having a magneto-resistance element using a magneto-resistance effect, which can reduce current consumption.

2. Description of the Related Art

FIG. 17 is a circuit diagram of a known magnetic detection device. The magnetic detection device includes a sensor unit S and an integrated circuit (IC). The magnetic detection device shown in FIG. 17 is a NS detection sensor. The NS detection sensor detects both the positive and negative magnetic fields. The sensor unit S has a first bridge circuit BC1 including first magneto-resistance elements 2 such as a GMR element of which an electric resistance varies with an external magnetic field in a positive direction, and a second bridge circuit BC2 including second magneto-resistance elements 3 such as a GMR element of which an electric resistance varies with an external magnetic field in a negative direction. “An external magnetic field in the positive direction” generally indicates the external magnetic field in any random direction. However, FIG. 17 indicates the external magnetic field in a direction when the resistance of the first magneto-resistance elements 2 varies, but the resistance of the second magneto-resistance elements 3 does not vary (i.e. functions as a fixed resistance element). Additionally, “An external magnetic field in a negative direction” indicates an opposite direction of the external magnetic field in the positive direction, and FIG. 17 indicates the external magnetic field in a direction when the resistance of the second magneto-resistance elements 3 varies, but the resistance of the first magneto-resistance elements 2 does not vary (i.e. functions as a fixed resistance element).

As shown in FIG. 17, each first magneto-resistance element 2 is connected to the corresponding fixed resistance element 4 to form a series circuit, and the first bridge circuit BC1 is formed by connecting each series circuit with each other in parallel. Each output portion of two series circuits forming the first bridge circuit BC1 is connected to a first differential amplifier 6. Additionally, as shown in FIG. 17, each second magneto-resistance element 3 is connected to the corresponding fixed resistance element 5 to form a series circuit, and the second bridge circuit BC2 is formed by connecting each series circuit with each other in parallel. Each of the output portions of two series circuits forming the second bridge circuit BC2 are connected to a second differential amplifier 7.

Inside the integrated circuit 1, there are provided with not only the differential amplifiers 6 and 7, but also Schmitt trigger type comparators 12 and 13, latch circuits 8 and 9, and the like. An external magnetic field detection signal is output from external output terminals 10 and 11.

When the external magnetic field in the positive direction acts on the magnetic detection device as shown in FIG. 17, the resistance of the first magneto-resistance element 2 forming the first bridge circuit BC1 varies. As a result, an output of the first bridge circuit BC1 is amplified in the first differential amplifier 6, and the detection signal caused by the amplified output is generated, then the detection signal is outputted from the first external output terminal 10. On the other hand, when the external magnetic field in the negative direction acts on the magnetic detection device, then the resistance of the second magneto-resistance element 3 forming the first bridge circuit BC2 varies. As a result, an output of the second bridge circuit BC2 is amplified in the second differential amplifier 7, and the detection signal caused by the amplified output is generated, then the detection signal is outputted from the second external output terminal 11.

As mentioned above, the magnetic detection device shown in FIG. 17 includes a NS detection sensor detecting the external magnetic field in both the positive and negative directions.

The following references are examples of the related art: JP-A-2004-77374, JP-A-2004-180286, JP-A-2005-214900, JP-A-2003-14833, JP-A-2003-14834, JP-A-2003-121268, and JP-A-2004-304052.

However, in a structure of the known magnetic detection device shown in FIG. 17, in order to adequately control a potential of each output portions of the bridge circuit as a central potential, the element resistance of fixed resistance elements 4 and 5 connected to magneto-resistance elements 2 and 3 in series need to be disposed near the magneto-resistance elements 2 and 3 respectively.

Since the element resistance of magneto-resistance elements 2 and 3 are several kΩ, the fixed resistance elements 4 and 5 need to decrease up to several kΩ.

Likewise, in the known structure, the element resistance of the fixed resistance elements 4 and 5 can not increase totally independently of the element resistance of the magneto-resistance elements 2 and 3. Because of the decrease in size of the magnetic detection device, a space for forming each element constituting the sensor unit S becomes smaller and thus the element resistance can not be sufficiently increased, thereby causing the increase in current consumption.

As shown in FIG. 17, the NS detection sensor needs many elements to form the sensor unit S. Specifically, in order to form the NS detection sensor, two bridge circuits, BC1 and BC2, are needed, for a total of eight elements, where the space for forming the sensor unit S becomes smaller, thereby limiting the element resistance in an element configuration of the known sensor unit S.

### SUMMARY OF THE INVENTION

The present invention solves the above mentioned problems. It is an object of the invention to provide a magnetic detection device able to reduce current consumption.

According to an aspect of the invention, there is provided a magnetic detection device including a bridge circuit formed by connecting a first series circuit to a second series circuit, wherein a plurality of resistance elements included in the first series circuit in parallel, wherein at least one of a plurality of resistance elements included in the first series circuit includes a magneto-resistance element using a magneto-resistance effect, of which an electric resistance varies with an external magnetic field. A plurality of resistance elements included in the second series circuit include fixed resistance elements of which an electric resistance does not vary according to the external magnetic field, and wherein an element resistance of the fixed resistance elements included in the second series circuit is larger than that of the element resistance of the resistance element included in the first series circuit.

In the element configuration of the bridge circuit, only the fixed resistance elements are connected to the second series circuit. Therefore, when the fixed resistance elements are formed, the element resistance of the fixed resistance elements need not to be adjusted to be equal to the element resistance of the magneto-resistance element in the same way as the fixed resistance elements, which are connected the magneto-resistance element in series. Namely, a degree of freedom increases when choosing a material, whereby the potential of an output portion can be controlled as a central potential. Accordingly, the element resistance of the fixed resistance elements included in the second series circuit can increase more than the element resistance of the resistance elements included in the first series circuit, thereby reducing current consumption.

Additionally, the sensor unit including the first series circuit and the integrated circuit connected to the sensor unit, outputting a magnetic field detection signal, are disposed on the substrate. It is preferable that the second series circuit is fitted into the integrated circuit. Hence, the space for forming the sensor unit is extended with the consequence that a degree of freedom increases when designing and the element resistance of the resistance element included in the first series circuit can increase, whereby the element resistance of each resistance element included in the sensor unit can increase. Consequently, current consumption can be effectively reduced. In addition, the fixed resistance elements included in the second series circuit can be formed of a high resistance material having a high sheet resistance.

The device includes a third series circuit, wherein the magneto-resistance element provided in the first series circuit is an element using a magneto-resistance effect, of which an electric resistance varies with a variation in magnitude of an external magnetic field of one direction, the third series circuit include the magneto-resistance element of which the electric resistance varies with an external magnetic field of the direction opposite to the one direction. A first bridge circuit for detecting the external magnetic field in the one direction is formed by connecting the first series circuit to the second series circuit in parallel, and a second bridge circuit for detecting the external magnetic field in the opposite direction formed by connecting the second series circuit to the third series circuit in parallel. Accordingly, the device can be performed as a NS detection sensor. The third series circuit is used as a common circuit connecting to the first bridge circuit and the second bridge circuit, whereby the number of elements forming two bridge circuits can be reduced. Consequently, because the space for forming each resistance element can be increased, the degree of freedom increases. The element resistance of each resistance element can be formed of a high resistance material, thereby effectively reducing current consumption.

Since a plurality of resistance elements included in the third series circuit are formed of the same material layer, the element resistance of the resistance elements can be adjusted to be equal respectively. Accordingly, the potential of the output portion is kept up as a central potential. Moreover, the irregularity of the temperature coefficient (TCR) can be suppressed. As a result, it may suppress the irregularity of the central potential according to a variation of temperature, and thereby improving an operational stability.

Besides, the device includes the sensor unit including the first series circuit and the third series circuit, and the integrated circuit connected to the sensor unit so as to output the magnetic field detection signal, disposed on the substrate. It is preferable that the second series circuit is fitted into the integrated circuit. Accordingly, the space for forming the sensor unit can be extended, whereby the degree of freedom increases. Consequently, the element resistance of the resistance element included in the first series circuit and the third series circuit can be increased. Namely the element resistance of the resistance element included in the sensor unit can increase with the consequence that current consumption can be effectively reduced. In addition, the fixed resistance elements included in the second series circuit can be formed of a high resistance material having a high sheet resistance.

Additionally, it is preferable that the integrated circuit is formed on the substrate and the sensor unit is formed on the integrated circuit with an insulating layer interposed therebetween. According to a lamination structure, the space for forming the element of sensor unit can be extended. Thus, the degree of freedom increases when designing the structure of the substrate and moreover the element resistance of the resistance element included in the sensor unit improves, thereby effectively reducing current consumption.

A plurality of resistance elements included in the first series circuit are formed of the same material layer. Accordingly, the potential of the output portion can be adequately controlled as the central potential and the irregularity of the temperature coefficient (TCR) can be suppressed as well. As a result, it may suppress the irregularity of the central potential according to the variation of temperature, and thereby improving an operational stability.

A plurality of fixed resistance elements included in the second series circuit are formed of the same material layer. Accordingly, the potential of the output portion can be adequately controlled as the central potential and the irregularity of the temperature coefficient (TCR) can be suppressed as well. As a result, it may suppress the irregularity of the central potential according to the variation of temperature, and thereby improving an operational stability.

It is more effective when the fixed resistance element is formed of silicon (Si). Especially, by fitting the fixed resistance elements into the integrated circuit, the fixed resistance elements can be formed of silicon like the other resistance elements formed in the integrated circuit. Specifically, by forming the fixed resistance elements of silicon, the element resistance can be increased up to several tens of kΩ. The element resistance of the known fixed resistance elements used as shown in FIG. 17 can be actually made up to several tens of times, thereby more effectively reducing current consumption.

In conclusion, current consumption can be effectively reduced.

### BRIEF DESCRIPTION OF THE DRAWINGS

FIG. 1 is a circuit diagram illustrating a state of an external magnetic field detection circuit in the positive direction of a magnetic detection device.

FIG. 2 is a circuit diagram illustrating a state of the external magnetic field detection circuit in the negative direction of the magnetic detection device according to the embodiment

FIG. 3 is a graph (curve R-H) illustrating a hysteresis characteristic of a first magneto-resistance element.

FIG. 4 is a graph (curve R-H) illustrating a hysteresis characteristic of a second magneto-resistance element.

FIG. 5 is a partially enlarged perspective view of the magnetic detection device illustrating a shape of a resistance element of a sensor unit of the magnetic detection device according to the embodiment.

FIG. 6 is a partially sectional view of the magnetic detection device taken along Line A-A of FIG. 5.

FIG. 7 is a partially sectional view illustrating a layered structure of the first magneto-resistance and the second magneto-resistance.

FIG. 8 is a partially sectional view illustrating a layered structure of a fixed resistance element.

FIG. 9 is an example illustrating a use of the magnetic detection device according to the embodiment showing a foldable cellular phone having the magnetic detection device when the cellular phone is closed.

FIG. 10 is an example illustrating the use of the magnetic detection device according to the embodiment showing a foldable cellular phone having the magnetic detection device when the cellular phone is opened.

FIG. 11 is an example illustrating the use of the magnetic detection device according to the embodiment showing a foldable cellular phone having the magnetic detection device and a magnet disposed opposite to the direction of FIG. 9.

FIG. 12 is an example illustrating the use of the magnetic detection device according to the embodiment showing a foldable cellular phone having the magnetic detection device and a magnet disposed opposite to the direction of FIG. 10 when the cellular phone is opened.

FIG. 13 is an example illustrating the use of the magnetic detection device according to the embodiment showing a foldable cellular phone having the magnetic detection device when the cellular phone is opened.

FIG. 14 is an example illustrating the use of the magnetic detection device according to the embodiment showing a foldable cellular phone having the magnetic detection device when a first member is turned over.

FIG. 15 is an example illustrating the use of the magnetic detection device according to the embodiment showing a foldable cellular phone having the magnetic detection device illustrated in FIG. 13)

FIG. 16 is an example illustrating the use of the magnetic detection device according to the embodiment showing a foldable cellular phone having the magnetic detection device illustrated in FIG. 15.

FIG. 17 is a circuit diagram illustrating a known magnetic detection device.

### DESCRIPTION OF THE PREFERRED EMBODIMENT

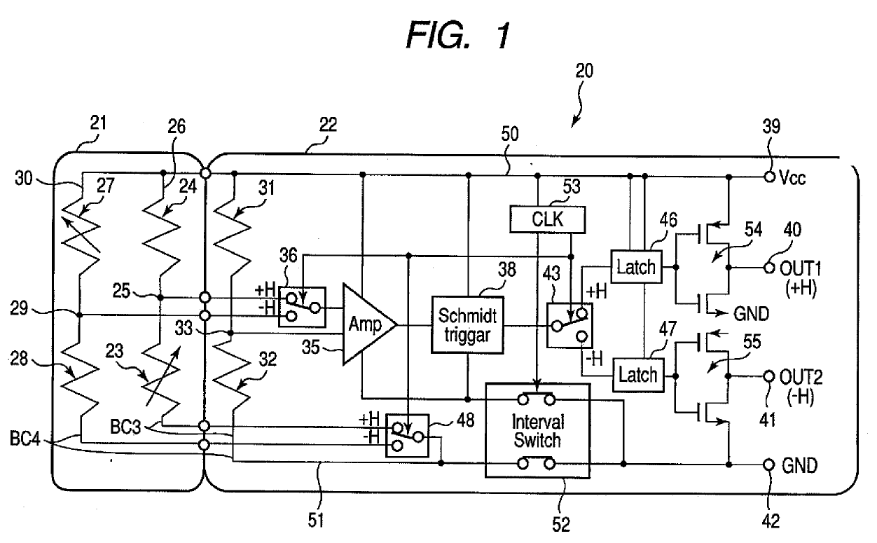

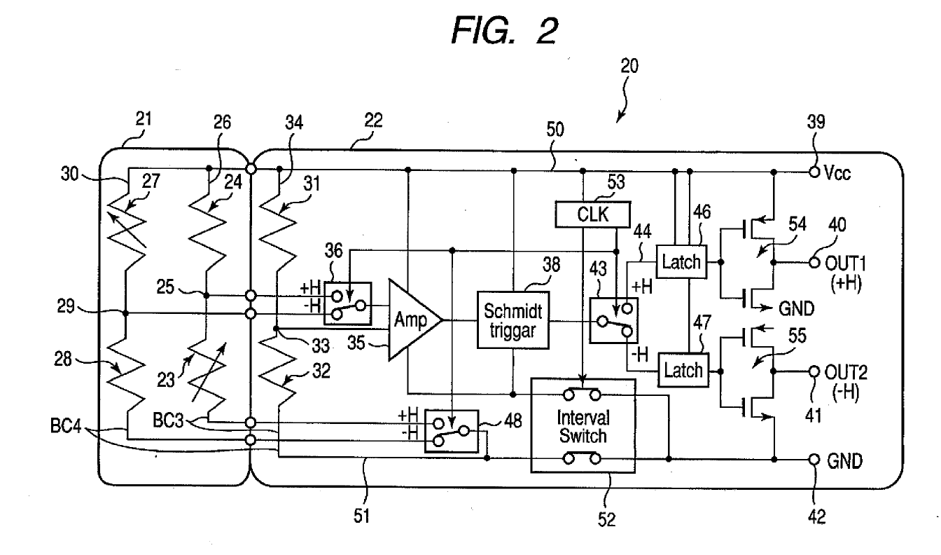

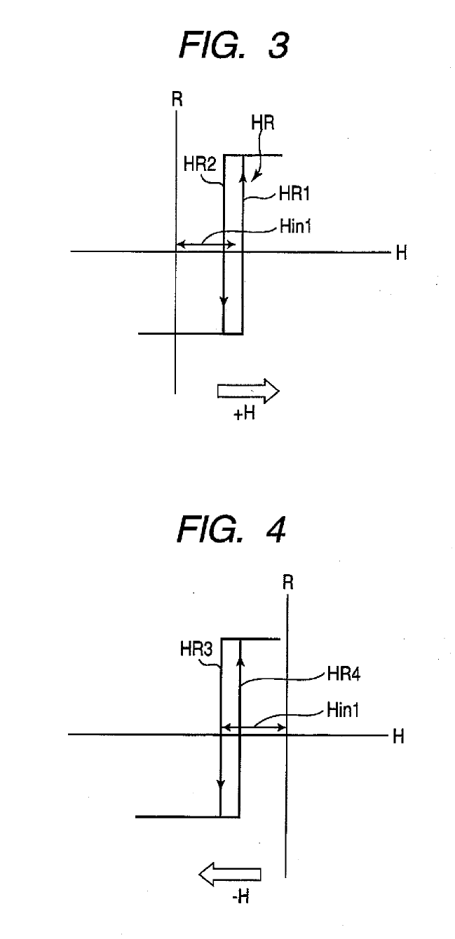

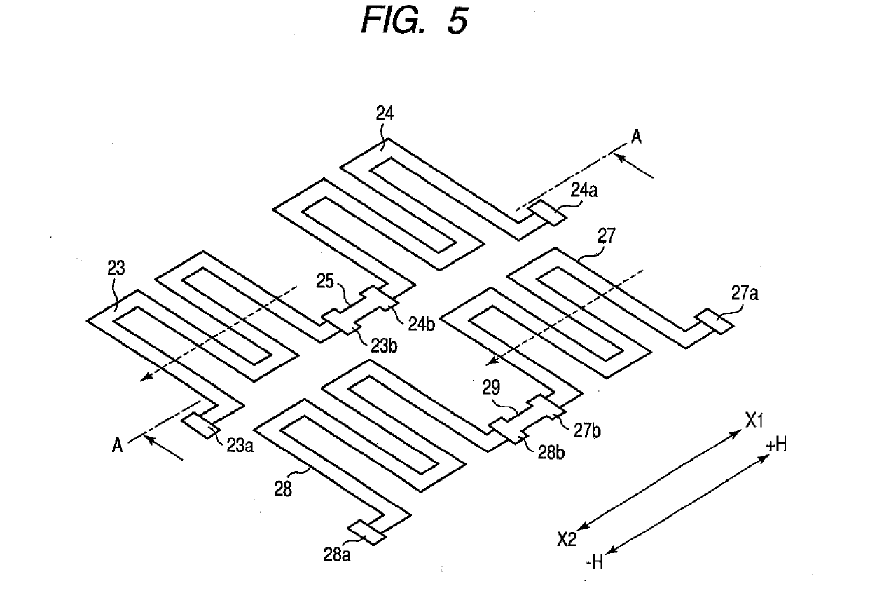

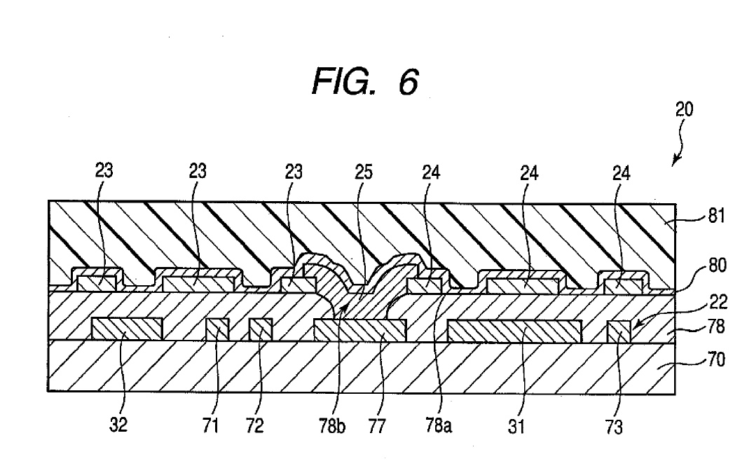

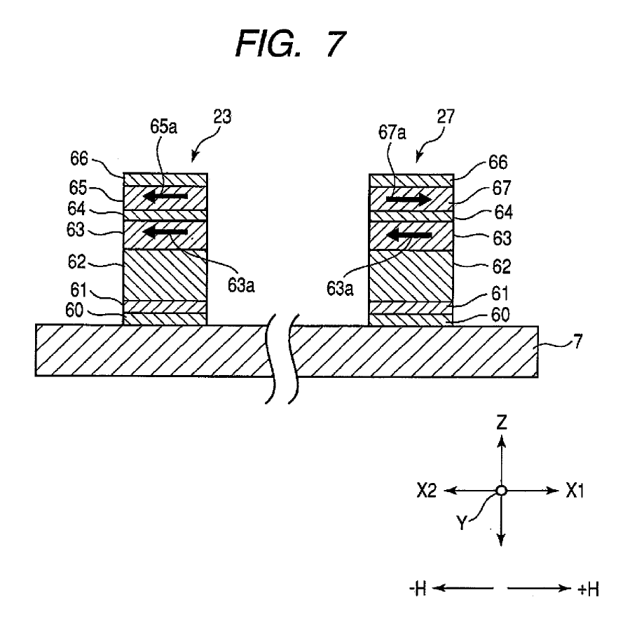

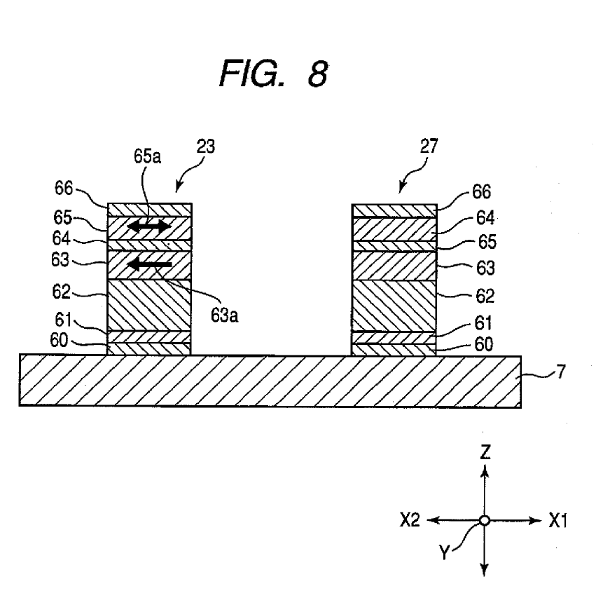

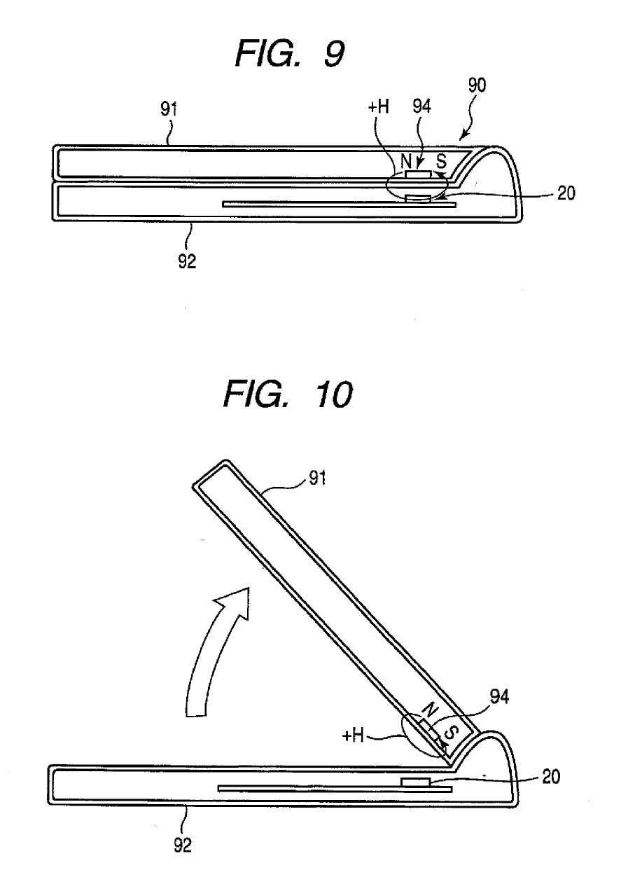

FIGS. 1 and 2 are circuit diagrams of a magnetic detection device 20 according to the embodiment. FIG. 3 is a graph (curve R-H) to illustrate a hysteresis characteristic of a first magneto-resistance element. FIG. 4 is a graph (curve R-H) illustrating the hysteresis characteristic of a second magneto-resistance element. FIG. 5 is a partially enlarged perspective view of the magnetic detection device 20 illustrating a shape of a sensor unit's resistance element of the magnetic detection device 20 in the embodiment. FIG. 6 is a partially sectional view of the magnetic detection device taken along Line A-A of FIG. 5. FIG. 7 is a partially sectional view illustrating a layered structure of the first magneto-resistance and the second magneto-resistance. FIG. 8 is a partially sectional view illustrating the structure of the layer of a fixed resistance element. FIGS. 9 to 16 are examples illustrating the use of the magnetic detection device according to the embodiment, showing partially plan views of the foldable cellular phone having the magnetic detection device.

The magnetic detection device 20 illustrated in FIG. 1 includes a sensor unit 21 and an integrated circuit (IC) 22.

The sensor unit 21 includes a first series circuit 26 of which a first resistance element (a first magneto-resistance effect element) 23 is connected to a second resistance element (a fixed resistance element in the embodiment) 24 in series via a first output portion (a connection portion) 25, and a third series circuit 30 of which a fifth resistance element (a second magneto-resistance effect element) 27 is connected to a sixth resistance element (the fixed resistance element in the embodiment) 28 in series via a third output portion (the connection portion) 29.

Additionally, the integrated circuit 22 includes a second series circuit 34 of which a third resistance element (the fixed resistance element) 31 is connected to a fourth resistance element (the fixed resistance element) in series 32 via a second output portion 33.

As mentioned above, “the resistance element” is denoted from first to the sixth. Hereinafter, each resistance element is denoted as “the magneto-resistance effect element” and “the fixed resistance element” in the following. When it is not necessary to distinguish between “the magneto-resistance effect element” and “the fixed resistance element”, a phrase “a resistance element” will be used.

The second series circuit 34 is a common circuit, thereby forming a bridge circuit with the first series circuit 26 and the third series circuit 30 respectively. Hereinafter, a bridge circuit formed by connecting the first series circuit 26 to the second series circuit 34 in parallel will be designated as a first bridge circuit BC3 and the bridge circuit formed by connecting the third series circuit 30 to the second series circuit 34 in parallel will be designated as a second bridge circuit BC4.

As shown in FIG. 1, the first bridge circuit BC3 is formed as the first resistance element 23 connected to the fourth resistance element 32 in parallel, and the second resistance element 24 is connected to the third resistance element 31 in parallel. The second bridge circuit BC4 is formed as the fifth resistance element 27 connected to the third resistance element 31 in parallel and the sixth resistance element 28 is connected to the fourth resistance element 32 in parallel.

As shown in FIG. 1, the integrated circuit 22 includes an input portion (power) 39, an earth terminal 42, and two external output terminals 40 and 41. The input portion (power) 39, the earth terminal 42, and two external output terminals 40 and 41 are electrically connected to a terminal of another device, as not shown in the drawings, by a wire bonding method or a die bonding method.

A signal line 50 connected to the input portion 39 and the signal line 51 connected to the earth terminal 42 are connected to electrodes on the ends of the both sides of the first series circuit 26, the third series circuit 30, and the second series circuit 34.

As shown in FIG. 1, the integrated circuit 22 includes one differential amplifier 35 and one of a + input portion and a − input portion of the differential amplifier 35 is connected to the second output portion 33 of the second series circuit 34.

The first output portion 25 of the first series circuit 26 and the third output portion 29 of the third series circuit 30 are connected to the input portion of the first switch circuit (a first switch portion) 36 respectively. The output portion of the first switch circuit 36 is connected to one of the − input portion and the + input portion (the input portion of which the second portion 33 is not connected).

As shown in FIG. 1, the output terminal of the differential amplifier 35 is connected to a Schmitt trigger-type comparator 38. The output terminal of the comparator 38 is connected to the input portion of the second switch circuit (the second switch portion) 43. The output terminal of the second switch circuit 43 is connected to two latch circuits 46 and 47, thereby connecting to a first external output terminal 40 and a second external output terminal 41 respectively via FET circuits 54 and 55. The FET circuits 54 and 55 are used as logic circuits.

As shown in FIG. 1, the integrated circuit 22 includes a third switch circuit 48. The output terminal of the third switch circuit 48 is connected to the signal line 51, which is connected to the earth terminal 42. The input portion of the third switch circuit 48 is connected to one end of the first series circuit 26 and the third series circuit 30.

As shown in FIG. 1, the integrated circuit 22 includes an interval switch circuit 52 and a clock circuit 53. When the interval switch circuit 52 is off, power to the integrated circuit 22 is turned off. The On and Off state of the interval switch circuit 52 is interlocked with a clock output of the clock circuit 53 and the interval switch circuit 52 functions to reduce power consumption.

The clock signal out of the clock circuit 53 is outputted to the first switch circuit 36, the second switch circuit 43, and the third switch circuit 48 respectively. When the clock signal is received in the first switch circuit 36, the second switch circuit 43, and the third switch circuit 48, the clock signal is distributed to perform the operation of the switch in a very short interval, thereby controlling the operation of the switch. For example, when one pulse of clock signal is several tens of msec, the switch operates in every several tens of μmsec.

The first magneto-resistance element 23 shows a magneto-resistance effect on the basis of a variation in the external magnetic field magnitude in a positive direction (+H), and the second magneto-resistance element 27 shows the magneto-resistance effect on the basis of the variation in the external magnetic field magnitude in a negative direction (−H), which is opposite to the positive direction,

Here, the external magnetic field in the positive direction (+H) indicates one of directions which is the X1 direction. The external magnetic field in the negative direction (−H) which is opposite to the positive direction, indicates the X2 direction.

Hereinafter, a layered structure and the hysteresis characteristic related to the first magneto-resistance element 23 and the second magneto-resistance element 27 will be described in detail.

As shown in FIG. 7, the first magneto-resistance element 23 and the second magneto-resistance element 27 have layers which are sequentially laminated from the bottom of an underlying layer 60, a seed layer 61, an antiferromagnetic layer 62, a fixed magnetic layer 63, a non-magnetic intermediate layer 64, free magnetic layers 65 and 67 (the free magnetic of the second magneto-resistance element 27 is a reference numeral 37), and a protection layer 66. The underlying layer 60 is formed of a non-magnetic material at least one element of such as Ta, Hf, Nb, Zr, Ti, Mo, W. The seed layer 61 is formed of NiFeCr or Cr and or like. The antiferromagnetic layer 62 is formed of an antiferromagnetic material containing element α (but, α is at least one element of Pt, Pd, Ir, Rh, Ru, Os) and Mn, or an antiferromagnetic material containing element α and element α′ (but, element α is at least one element of Ne, Ar, Kr, Xe, Be, B, C, N, Mg, Al, Si, P, Ti, V, Cr, Fe, Co, Ni, Cu, Zn, Ga, Ge, Zr, Nb, Mo, Ag, Cd, Sn, Hf, Ta, W, Re, Au, Pb, and a rare-earth elements and Mn. For example, the antiferromagnetic layer 62 is formed of IrMn or PtMn. The fixed magnetic layer 63 and the free magnetic layers 65 and 67 are formed of a magnetic material such as CoFe alloy, NiFe alloy, CoFeNi alloy and the like. The non-magnetic intermediate layer 64 is formed of Cu and the like. The protection layer 66 is formed of Ta and the like. The fixed magnetic layer 63 or the free magnetic layers 65 and 67 have a lamination layer ferri structure (A lamination structure has a sequential laminated order of the magnetic layer, the non-magnetic layer, and the magnetic layer. The non-magnetic layer is interposed between two magnetic layers which has an anti-parallel magnetization direction). Additionally, the fixed magnetic layer 63 or the free magnetic layers 65 and 67 may have the lamination structure of which a plurality of magnetic layers made of a different material are laminated.

In the first magneto-resistance element 23 and the second magneto-resistance element 27, the antiferromagnetic layer 62 is formed in contact with the fixed magnetic layer 63, whereby an exchanging coupling magnetic field (Hex) is made on an interface between the antiferromagnetic layer 62 and the fixed magnetic layer 63 by a heat treat in a magnetic field, thereby fixing the magnetization direction to one direction. FIGS. 5 and 7 indicate the magnetization direction 63a of the fixed magnetic layer as shown by an arrow. In the first magneto-resistance element 23 and the second magneto-resistance element 27, the magnetization direction 63a of the fixed magnetic layer 63 is the X1 direction (i.e. the positive direction).

Meanwhile, the magnetization direction of the free magnetic layers 65 and 67 is different between the first magneto-resistance element 23 and the second magneto-resistance element 27. As shown in FIG. 7, in the first magneto-resistance element 23, the magnetization direction 65a of the free magnetic layer 65 is shown in the X2 direction (i.e. the negative direction), which is same as the magnetization direction 63a of the fixed magnetic layer 63, but in the second magneto-resistance element 27, the magnetization direction 67a of the free magnetic layer 67 is shown in the X1 direction (the positive direction), which is the opposite of the magnetization direction 63a of the fixed magnetic layer 63.

When the external magnetic field in the positive direction (+H) acts, the magnetization 67a of the free magnetic layer 67 of the second magneto-resistance element 27 does not vary, but the magnetization 65a of the free magnetic layer 65 of the first magneto-resistance element 23 varies resulting in the resistance of the first magneto-resistance element 23 varying. FIG. 3 is the curve R-H illustrating the hysteresis characteristic of the first magneto-resistance element 23. Additionally, a vertical axis is the resistance R in the FIG. 3, but it may be a variation rate of the resistance (%). As shown in FIG. 3, when the external magnetic field is gradually increased from a non-magnetic field (zero) to the positive direction, a state of equilibrium between the magnetization 65a of the free magnetic layer 65 and the magnetization 63a of the fixed magnetic layer 63 is given away with the consequence that it becomes close to an antiparallel state, whereby the resistance R of the first magneto-resistance element 23 gradually becomes large, as shown in the curve HR1. When the external magnetic field in the positive direction (+H) is gradually decreases to the zero, the resistance R is gradually decreased, as shown along the curve HR2.

Likewise, in the first magneto-resistance element 23, a hysteresis loop HR surrounded by the curves HR1 and HR2 is formed according to the variation in the magnetic field magnitude of the external magnetic field in the positive direction (+H). A middle point of the hysteresis loop HR is a central value between a maximum resistance and a minimum resistance of the first magneto-resistance element 23 and a central value of a width of the hysteresis loop HR. The magnitude of the Hin1 (i.e. a first inter-layer coupling magnetic field) is determined by the magnitude of the magnetic field in the range of the center point of the hysteresis loop HR to the magnetic field line H=0 (Oe). As shown in FIG. 3, in the first magneto-resistance element 23, Hin1 (i.e. the first inter-layer coupling magnetic field) is shifted toward the magnetic field in the positive direction.

Meanwhile, when the external magnetic field in the negative direction (−H) acts, the magnetization 65a of the free magnetic layer 65 of the first magneto-resistance element 23 does not vary, but the magnetization 67a of the free magnetic layer 67 of the second magneto-resistance element 27 varies, which results in the resistance of the second magneto-resistance element 27 varying.

FIG. 4 is the curve R-H illustrating the hysteresis characteristic of the second magneto-resistance element 27. As shown in FIG. 4, when the external magnetic field is gradually increased from the non-magnetic field state (zero) to the negative direction, the anti-parallel state between the magnetization 67a of the free magnetic layer 67 and the magnetization 63a of the fixed magnetic layer 63 becomes close to the parallel state. Consequently, the resistance R of the second magneto-resistance element 27 is gradually decreased as shown along the curve HR3. Meanwhile, when the external magnetic field in the negative direction (−H) changes to the zero, the resistance R of the second magneto-resistance element 27 is gradually increased as shown along the curve HR4.

Likewise, in the second magneto-resistance element 27, a hysteresis loop HR surrounded by the curves HR3 and HR4 is formed according to the variation in the magnetic field magnitude of the external magnetic field in the negative direction (−H). The hysteresis loop HR is the central value between the maximum resistance and the minimum resistance of the second magneto-resistance element 27 and a central value of a width of the hysteresis loop HR is a middle point of the hysteresis loop HR. The magnitude of the Hin2 (i.e. a second inter-layer coupling magnetic field) is determined by the magnitude of the magnetic field in the range of the center point of the hysteresis loop HR to the magnetic field line H=0 (Oe). As shown in FIG. 3, in the second magneto-resistance element 27, Hin2 (i.e. the second inter-layer coupling magnetic field) is shifted toward the magnetic field in the negative direction.

in the embodiment, the Hin1 (i.e. the first inter-layer coupling magnetic field) of the first magneto-resistance element 23 is shifted to the magnetic field in the positive direction. Then the Hin2 (i.e. the second inter-layer coupling magnetic field) of the second magneto-resistance element 27 is shifted to the magnetic field in the negative direction.

The Hin1 and Hin2, the inter-layer coupling magnetic field, has an opposite magnetic field direction illustrated in FIGS. 3 and 4, can be extracted, for example, by adequately adjusting a gas flow (a gas pressure) or a voltage at the time of performing a plasma treatment (PT) on the surface of the non-magnetic intermediate layer 64. According to the level of the gas flow (the gas pressure) and the voltage, a variation of the Hin (i.e. the inter-layer coupling magnetic field) may be achieved. When the level of the gas flow (the gas pressure) or the voltage increases, the Hin (i.e. the inter-layer coupling magnetic field) can vary from the negative direction to the positive direction. In addition, the magnitude of the Hin (i.e. the inter-layer coupling magnetic field) varies by the thickness of the non-magnetic intermediate layer 64. The magnitude of the Hin (i.e. the inter-layer coupling magnetic field) can be adjusted by changing the thickness of the film of the antiferromagnetic layer when it is sequentially laminated from the bottom of the antiferromagnetic layer, the fixed magnetic layer, the non-magnetic intermediate layer, and the free magnetic layer.

In the first magneto-resistance element 23, the Hin1 (i.e. the first inter-layer coupling magnetic field) is in the positive direction with the consequence that an interaction of the magnetization to be parallel acts between the fixed magnetic layer 63 and the free magnetic layer 65. In the second magneto-resistance element 27, the Hin2 (i.e. the second inter-layer coupling magnetic field) is in the negative direction with the consequence that an interaction of the magnetization to be anti-parallel acts between the fixed magnetic layer 63 and the free magnetic layer 67. An exchanging coupling magnetic field (Hex) in the same direction between the antiferromagnetic layer 62 and the fixed magnetic layer 63 of each magneto-resistance element 23 and 27 is performed by the heat treatment, whereby the magnetization 63a of the fixed magnetic layer 63 of each magneto-resistance element 23 and 27 can be fixed in the same direction. Additionally, the above mentioned interaction acts between the fixed magnetic layer 63 and the free magnetic layers 65 and 67 to be the state of magnetic field as shown in FIG. 7.

The first magneto-resistance element 23 and the second magneto-resistance element 27 uses the method of a giant magneto-resistance (a GMR effect), but an AMR element using an anisotropic magneto-resistance and a TMR element using a runnel magneto-resistance except for a GMR element maybe used.

Meanwhile, the fixed resistance element 24, which is connected to the first magneto-resistance element 23 in series, has a different lamination order from the first magneto-resistance element 23, which is formed of the same material layer as the first magneto-resistance element 23. Namely, as shown in FIG. 8, the fixed resistance element 24 is sequentially laminated from the bottom of the underlying layer 60, the seed layer 61, the antiferromagnetic layer 62, the first magnetic layer 63, the second magnetic layer 65, a non-magnetic intermediate layer 64, and the protection layer 66. The first magnetic layer 63 corresponds to the fixed magnetic layer 63 included in the first magneto-resistance element 23. The second magnetic layer 65 corresponds to the free magnetic layer 65 included in the first magneto-resistance element 23. As shown in FIG. 8, in the first fixed resistance element 24, the first magnetic layer 63 and the second magnetic layer 65 are sequentially laminated on the antiferromagnetic layer 62, whereby all of the magnetization of the first magnetic layer 63 and the second magnetic layer 65 are fixed by the exchanging coupling magnetic field (HEX) which is generated between the antiferromagnetic layer 62. The magnetization of the second magnetic layer 65 does not vary due to the external magnetic field, which is the same as the free magnetic layer 65 of the first magneto-resistance element 23.

As shown in FIG. 8, when each layer of the fixed resistance element 24 is formed of the material same as each layer of the first magneto-resistance element 23, the element resistance of the first magneto-resistance element 23 and the fixed resistance element 24 are almost equal. Consequently, the potential of the first output portion 25 in the state of non-magnetic field can be adequately controlled as a central potential. The irregularity of the temperature coefficients (TCR) of the first magneto-resistance element 23 and the fixed resistance element 24 can be suppressed, thereby improving an operational stability because the irregularity of the central potential according to a temperature variation can be suppressed. Additionally, it is preferable when the material is same and the thickness corresponding to the first magneto-resistance element 23 is the same.

As described above, although not shown in the drawings, the fixed resistance element 28 which is connected to the second magneto-resistance element 27 in series, has a different lamination order from the second magneto-resistance element 27, but uses the same material layer as the second magneto-resistance element 27.

Meanwhile, the resistance element included in the second series circuit 34 is formed of only the fixed resistance element. As the magneto-resistance element is not included, the fixed resistance elements 31 and 32 in the integrated circuit 22 are not necessary formed of the same as the material layer of the magneto-resistance element.

That is to say when the fixed resistance elements 31 and 32 are the fixed resistance element which has the almost same resistance element formed of the same material layer, the layer structure is not limited.

Consequently, when the fixed resistance elements 31 and 32 are formed, there is some degree of freedom when choosing the material than when forming the fixed resistance element 24 included in the first series circuit 26 and the fixed resistance element 28 included in the third series circuit 30.

In the embodiment, the fixed resistance elements 31 and 32 are formed in the integrated circuit 22. The fixed resistance elements 31 and 32 are not elements that detect the external magnetic field. However, in the embodiment, the central potential of the second series circuit 34 is used as a reference potential between the first bridge circuit BC3 and the second bridge circuit BC4. Consequently, the fixed resistance elements 31 and 32 can be fitted into the integrated circuit 22.

In the embodiment, the fixed resistance elements 31 and 32 can be formed of silicon (Si) which has very high resistance, similar to the other resistance elements disposed in the integrated circuit 22. The element resistance of the fixed resistance elements 31 and 32 can increase up to several tens of kΩ.

Next, the partially sectional view of the magnetic detection device 20 in the embodiment in FIG. 6 will be described. As shown in FIG. 6, in the magnetic detection device 20, an underlying film made of silica (SiO2) (not shown) is formed of a predetermined thickness on the substrate 70 formed of, for example, Si (Si).

Active elements 71 to 73 such as a differential amplifier or a comparator a third resistance element 31, a fourth resistance element 32, an interconnection layer 77, and the like are formed on the underlying film. The interconnection layer 77 is formed of for example, aluminum (Al).

As shown in FIG. 6, front surfaces of the substrate 70 and the integrated circuit 22 are covered with an insulating layer 78 formed of a resistance element layer and the like. In the insulating layer 78, a through hole 78b is formed on a certain part of the interconnection layer 77 and the front surface of the interconnection layer 78b is disclosed from the through hole 78b.

The front surface 78a of the insulating layer 78 is formed to be a flat surface. On the flat front surface 78a of the insulating layer 78, the first resistance element 23, the second resistance element 24, the fifth resistance element 27, and the sixth resistance element 28 are formed in a meandering shape as shown in FIG. 5, thereby increasing the element resistance of each element.

As shown in FIG. 5, electrodes 23a, 23b, 24a, 24b, 27a, 27b, 28a, and 28b are formed on both ends of each element. The electrode 23b of the first resistance element 23 is connected to the electrode 24b of the second the resistance element 24 via the first output portion 25. As shown in FIG. 6, the first output portion 25 is electrically connected to the interconnection layer 77. Similarly, electrode 27b of the fifth resistance element 27 is connected to the electrode 28b of the sixth resistance element 28 via the third output portion 29. The ted output portion 29 is electrically connected to the interconnection layer not shown in the drawings.

As shown in FIG. 6, the front surfaces of the element, the electrode, and the output portion are covered with the insulating layer 80 formed of, for example, alumina or silica. The magnetic detection device 20 is packaged using molded resin 81.

In the embodiment, as shown in FIG. 6, the integrated circuit 22 and the sensor unit 21 are laminated via the insulating layer 78 on the substrate 70, whereby a large space of the front surface 78a of the insulating layer can be used as a space for forming the sensor unit 21. Consequently, the space for forming each resistance elements 23, 24, 27, and 28 are extended. When each resistance element 23, 24, 27, and 28 is disposed in the meandering shape as shown in FIG. 5, the length of the elements can increase, thereby increasing the element resistance of each resistance element.

In the embodiment, since the third resistance element 31 and the fourth resistance element included in the second series circuit 34 are fitted into the integrated circuit 22, the number of elements included in the sensor unit 21 can be reduced. Additionally, the space for forming resistance elements 23, 24, 27, and 28 included in the sensor unit 21 can be extended.

In the embodiment, the second series circuit 34 is used as the common circuit by both of the BC3 (i.e. the first bridge circuit) and the BC4 (i.e. the second bridge circuit). The central potential of the second series circuit 34 is used as the reference potential by the BC3 (i.e. the first bridge circuit) and the BC4 (i.e. second bridge circuit).

In the past, although the NS detection sensor used the magneto-resistance element totally requires at least eight elements, but in the embodiment six elements are used to form the sensor unit as shown in FIGS. 1 and 2, thereby decreasing the number of elements. In the past, all of eight elements needed to form the sensor unit 21 on the front surface 78a of the insulating layer 78 as shown in FIG. 6. However, as described above in the embodiment, the second series circuit 34 can be fitted into the integrated circuit 22 and the total number of elements forming the sensor unit 21 can decrease as well. Because of the decrease in size of the magnetic detection device 20, the space for forming resistance elements 23, 24, 27, and 28 can be extended respectively.

First, it will be described when the external magnetic field does not act on the magnetic detection device 20 in the embodiment. Considering aforementioned state, the resistance of both the first magneto-resistance element 23 and the second magneto-resistance element 27 does not vary. When the clock signal from the clock circuit 53 is sent to the first switch circuit 36, the second switch circuit 43, and the third switch circuit 48 respectively, it is switched over at every several tens of μsec, in the state of the external magnetic field detection circuit in the positive direction (+H). The first switch 36 connects between the first output portion 25 of the first series circuit 26 and the differential amplifier 35, the second switch 43 connects between the comparator 38 and the first external output terminal 40 and the third terminal 48 connects between the first series circuit 26 and the earth terminal 42 as shown in FIG. 1. When the state of the external magnetic field detection circuit is in the negative direction (−H), the first switch 36 connects between the third output portion 29 of the third series circuit 30 and the differential amplifier 35, the second switch 43 connects between the comparator 38 and the second external output terminal 41 and the third terminal 48 connects between the third series circuit 30 and the earth terminal 42 as shown in FIG. 2.

When the external magnetic field is not reached to the magnetic detection device, in the state of the external magnetic field detection circuit in the positive direction (+H) as shown in FIG. 1, the differential potential between the first output portion 25 of the first bridge circuit BC3 and the second output portion 33, and in the state of the external magnetic field detection circuit in the negative direction (−H) as shown in FIG. 2, the differential potential between the third output portion 29 of the second bridge circuit BC4 and the second output portion 33 are almost zero. When the differential potential which is zero is outputted from the differential amplifier 35 to the comparator 38, in the comparator 38, such a high level signal is controlled so as to be outputted from the first external output terminal 40 and the second external output terminal 41 through the latch circuits 46 and 47, and the FET circuit 54 according to the Schmitt trigger input.

When the external magnetic field in the positive direction (+H) acts on the magnetic detection device 20 of the embodiment, the resistance of the first magneto-resistance element 23 varies. As a result, the central potential in the first output portion 25 of the first series circuit 26 also varies. For example, when the circuit configuration in FIG. 1 has the hysteresis characteristic in FIG. 3, as a specific example the potential increases.

In the state of the external magnetic field (+H) detection circuit in the positive direction as shown in FIG. 1, the central potential of the second output portion 33 in the second series circuit 34 is set to a reference potential, and the differential potential between the first output portion 25 and the second output portion 33 of the first bridge circuit BC3 is generated from the differential amplifier 35, and outputted to the comparator 38. The comparator 38 changes the differential potential to shape into a pulse signal by using the Schmitt trigger input, and a shaped detection pulse signal is outputted from the first external output terminal 40 through the latch circuit 46 and the FET circuit 54. When the magnitude of external magnetic field in the positive direction (+H) is not less than a predetermined magnitude, the detection signal is controlled so as to output a low level signal from the first external output terminal 40. Additionally, the magnitude of the external magnetic field in the positive direction (+H) is smaller than a predetermined magnitude, the detection signal is controlled so as to generate a high level signal in the comparator 38, and it is not different from when the external magnetic field does not act.

Contrarily, when the external magnetic field in the positive direction (+H) is acting, even the magnetic detection device is switched over to the state of the external magnetic field (−H) detection circuit of the negative direction in FIG. 2, the resistance of the second magneto-resistance element 27 does not vary. Therefore, in the same manner as the external magnetic field does not act, the high level signal is controlled so as to be outputted from the second external output terminal 41.

Likewise, when the external magnetic field having the predetermined magnitude and more in the positive direction (+H) acts on the magnetic detection device, the high level signal or the low level signal changes into an opposite level signal. Therefore, the first external output terminal 40 performs the function to be capable of detecting the action of the external magnetic field in the positive direction (+H) by the variation of the signal level.

In the same manner, when the external magnetic field in the negative direction (−H) acts on the magnetic detection device 20 of the embodiment, the resistance of the second magneto-resistance element 27 varies. As a result, the central potential in the second output portion of the third series circuit 30 varies. Specifically the potential increases.

In the state of the external magnetic field detection circuit in the negative direction (−H) as shown in FIG. 2, the central potential of the second output portion 33 in the second series circuit 34 is set to a reference potential, and the differential potential between the third output portion 29 and the second output portion 33 of the second bridge circuit BC4 formed of the third series circuit 30 and the second series circuit 34 is generated from the differential amplifier 35, and outputted to the comparator 38. The comparator 38 changes the differential potential to shape into the pulse signal by using the Schmitt trigger input, and shaped detection pulse signal is outputted from the second external output terminal 41 through the latch circuit 47 and the FET circuit 55. When the magnitude of external magnetic field in the negative direction (−H) is not less than a predetermined magnitude, the detection signal is controlled so as to output the low level signal from the second external output terminal 41. Additionally, the magnitude of the external magnetic field (+H) in the negative direction is smaller than a predetermined magnitude, the detection signal is controlled so as to generate the high level signal in the comparator 38, and it is not different from when the external magnetic field does not act.

Contrarily, when the external magnetic field in the negative direction (−H) acts, even the magnetic detection device is switched over to stats of the external magnetic field (+H) detection circuit in the positive direction in FIG. 2, the resistance of the first magneto-resistance element 23 does not vary. Therefore, in the same manner as the external magnetic field does not act, the high level signal is controlled so as to be outputted from the first external output terminal 40.

Likewise, when external magnetic field having the predetermined magnitude and more in the negative direction (−H) acts on the magnetic detection device, the high level signal or the low level signal changes into an opposite level signal. Therefore, the second external output terminal 41 performs the function to be capable of detecting the action of the external magnetic field in the negative direction (−H) by the variation of the signal level.

The detection signal outputted from the first external output terminal 40 or the second external output terminal 41 is used as a processing circuit and the like for another device as not shown in the drawings. More specifically, the detection signal is used to detect whether a foldable cellular phone, of which will be described later, is opened or closed.

The magnetic detection device 20 in the embodiment characteristically has the second series circuit 34 including the resistance element and the fixed resistance elements 31 and 32 which are connected to the first series circuit 26 in parallel including the first magneto-resistance element 23 and the third series circuit 30 including the second magneto-resistance element 27. The element resistance of the fixed resistance elements 31 and 32 is larger than that of the resistance elements 23, 24, 27, and 28 included in the sensor unit 21.

In the embodiment, the magneto-resistance element is not included in the resistance element included in the second series circuit 34, and only the fixed resistance elements 31 and 32 are included in the second series circuit 34. Although the fixed resistance element 24 included in the first series circuit 26 or the fixed resistance element 28 included in the third series circuit 30 connected to the magneto-resistance element in series respectively need be formed of the same material layer as the magneto-resistance element in order to adequately control the central potential, the second series circuit has no limitation when selecting the material layer.

Accordingly, the degree of freedom increases when selecting the material of the fixed resistance elements 31 and 32, whereby the element resistance of the fixed resistance elements 31 and 32 can be larger than that of the resistance elements 23, 24, 27, and 28 included in the first series circuit 26 and the second series circuit 30, and thereby reducing current consumption.

In the embodiment, the fixed resistance elements 31 and 32 included in the second series circuit 34 are incorporated into the integrated circuit 22. Although it is an aspect of the embodiment that the fixed resistance elements 31 and 32 are incorporated into the sensor unit 21 in the embodiment, the fixed resistance elements 31 and 32 can be formed of silicon (Si) of which the sheet resistance is very high like the other resistance elements under the same process by fitting the fixed resistance elements 31 and 32 into the integrated circuit 22. When the fixed resistance elements 31 and 32 are formed in the meandering shape as shown in FIG. 5, the length of the element can be formed having sufficient length within a limited area, and consequently it is preferable that the element resistance can be increased. However the space may not exist in the integrated circuit 22, and the element resistance of the fixed resistance elements 31 and 32 can be increased by using silicon (Si) having high sheet resistance. As an example, the element resistance of the resistance elements 23, 24, 27, and 28 included in the sensor unit 21 is generally in the range of two to three kΩ. The element resistance of the fixed resistance elements 31 and 32 included in the second series circuit 34 can increase up to thirty kΩ.

Since the fixed resistance elements 31 and 32 are simply fitted into the integrated circuit 22, the circuit configuration is not particularly complicated. As will be described later, the NS detection sensor in the embodiment needs one differential amplifier 35 and one comparator 38 to configure the circuit. Preferably, the circuit configuration can be simply configured, and thus one integrated circuit 22 can be realized as a small circuit.

The fixed resistance elements 31 and 32 fitted into the integrated circuit 22 can be formed by the process of a CVD and a sputtering such as a thin film forming process and a printing.

In order to adequately control the potential as the central potential out of the second output portion 33 of the second series circuit 34, it is preferable that the fixed resistance elements 31 and 32 need to be formed of the same material layer. Additionally, by forming the fixed resistance elements 31 and 32 of the same material layer, thereby the irregularity of the temperature coefficient (TCR) can be suppressed. Consequently, the irregularity of the central potential according to the variation of temperature can be suppressed, thereby improving the operational stability.

According to the embodiment, by fitting the fixed resistance elements 31 and 32 into the integrated circuit 22, the number of elements included in the sensor unit 21 can be decreased. That is to say, since the total number of elements included in the sensor unit 21 is four as shown in FIGS. 1, 2, 5, and 6, the space for forming each resistance element included in the sensor unit 21 can be extended. Especially, in the embodiment, the integrated circuit 22 and the sensor unit 21 are laminated on the substrate 70 with the insulating layer 78 interposed therebetween. It is the aspect of the embodiment that the integrated circuit 22 and the sensor unit 21 are arranged on the surface to form the structure. However, the broaden area of the front surface 78a of the insulating layer 78 can be used as the space for forming the sensor unit 21 by laminating the integrated circuit 22 and the sensor unit 21 on the substrate 70 with the insulating layer interposed therebetween. In addition, the magnetic detection device 20 of the embodiment is the NS detection sensor, and the second series circuit 34 is used as the common circuit connected to the first bridge circuit BC3 and the second bridge circuit BC4. Consequently, the known NS detection sensor using the magneto-resistance element needs at least eight elements, but the device of the embodiment can be totally formed of six elements as shown in FIGS. 1 and 2, thereby reducing the number of elements.

As described above, the space for forming each element included in the sensor unit 21 can be effectively extended, hence the length of the element of the resistance elements 23, 24, 27, and 28 included in the sensor unit 21 can be formed longer than the known technology respectively. Accordingly, the element resistance of the resistance elements 23, 24, 27, and 28 can increase respectively. When the resistance element is formed in the meandering shape as shown in FIG. 5, the length of the element can be lengthened within the limited space for forming the element, thereby preferably increasing the element resistance.

In the embodiment, the central potential of the second series circuit 34 connected to the fixed resistance elements 31 and 32 in series is commonly used as the reference potential of the first bridge circuit BC3 and the second bridge circuit BC4. Additionally, the first switch circuit 36 is provided to alternatively switch over the connection between the first output portion 25 of the first series circuit 26 included in the first bridge circuit BC3 and the differential amplifier 35, and to alternatively switch over the connection between the third output portion 29 of the third series circuit 30 included in the second bridge circuit BC4 and the differential amplifier 35.

As described above, when the first switch circuit 36 is provided, even one differential amplifier 35 can alternatively extract two detection states of both the first the bridge circuit BC3 connected to the differential amplifier 35 in the state of detecting the external magnetic field in the positive direction (FIG. 1) and the second bridge circuit BC4 connected to the differential amplifier 35 in the state of detecting the external magnetic field in the negative direction (FIG. 2). Accordingly, the circuit is simply configured, whereby the differential potential of the differential amplifier 35 can be adequately extracted from both the first bridge circuit BC3 and the second bridge circuit BC4.

Namely, (FIG. 17), the known differential amplifier is provided in each bridge circuit, but in the embodiment two bridge circuits BC3 and BC4 are commonly connected to the differential amplifier 35 via the first switch circuit 36. In terms of a switch operation of the first switch circuit 36. Since two detection states of both the first bridge circuit BC3 connected to the differential amplifier 35 in the state of detecting the external magnetic field in the positive direction (FIG. 1) and the second bridge circuit BC4 connected to the differential amplifier 35 in the state of detecting the external magnetic field in the negative direction (FIG. 2) can be generated, consequently, even one differential amplifier 35 is enough and thus the number of the signal lines can decrease, thereby simply forming the circuit configuration and forming the circuit in decreased size as well.

In addition, the third switch circuit 48 is provided to switch over a correcting between the earth terminal 42 and the first series circuit 26, and to switch over a connecting between the earth terminal 42 and the third series circuit 30 in the embodiment.

Furthermore, the third switch circuit 48 connects the first series circuit 26 with the earth terminal 42 when the first switch circuit 36 connects the first bridge circuit BC3 with the differential amplifier 35, and the third switch circuit 48 connects the third series circuit 30 with the earth terminal 42 when the first switch circuit 36 connects the second bridge circuit BC4 with the differential amplifier 35. Accordingly, there is a turning off the electricity in the third series circuit 30 when the first bridge circuit BC3 is connected with the differential amplifier 35, and there is the turning off the electricity in the first series circuit 26 when the second bridge circuit BC4 is connected with the differential amplifier 35. As a result, the magnetic detection device can more effectively reduce current consumption.

In the embodiment, the use of the magnetic detection device 20 of the NS detection will be described. The magnetic detection device 20 of the embodiment can be used such as an open and close detecting device of the foldable cellular phone.

As shown in FIG. 9, the foldable cellular phone 90 includes a first member 91 and a second member 92. The first member 91 is a screen display portion, and the second member 92 is a manipulation portion. A facing surface of the first member 91 with the second member 92 includes a liquid crystal display (LCD), a receiver or the like. A facing surface of the second member 92 with the first member 91 includes various type buttons and a microphone. FIG. 9 illustrates the closing state of the foldable cellular phone 90. As shown in FIG. 9, the first member 91 has a magnet 94, and the second member 92 has the magnetic detection device 20 of the embodiment. Additionally, as shown in FIG. 9 the magnet 94 and the magnetic detection device 20 are disposed at positions opposed to each other in the closing state. Alternatively the magnetic detection device 20 may be disposed at a position departing from the direction parallel to an application direction of the external magnetic field other than the position facing the magnet 94.

In FIG. 9, the external magnetic field emitted from the magnet 94 in the positive direction (+H) acts on the magnetic detection device 20, and the external magnetic field (+H) is detected in the magnetic detection device 20, whereby the closing state of the foldable cellular phone 90 is detected.

Conversely, when the foldable cellular phone 90 is opened as shown in FIG. 10, the first member 91 is gradually withdrawn from the second member 92, accordingly the magnitude of the external magnetic field (+H) that acts on the magnetic detection device 20 gradually becomes smaller, and then the magnitude of the external magnetic field (+H) acting on the magnetic detection device 20 becomes zero. The magnitude of the external magnetic field (+H) acting on the magnetic detection device 20 is a predetermined magnitude or less, whereby the foldable cellular phone 90 is detected in an open state. For example, a backlight in a rear side of the liquid crystal display or the manipulation buttons is controlled so as to emit light by a control unit included in the foldable cellular phone 90.

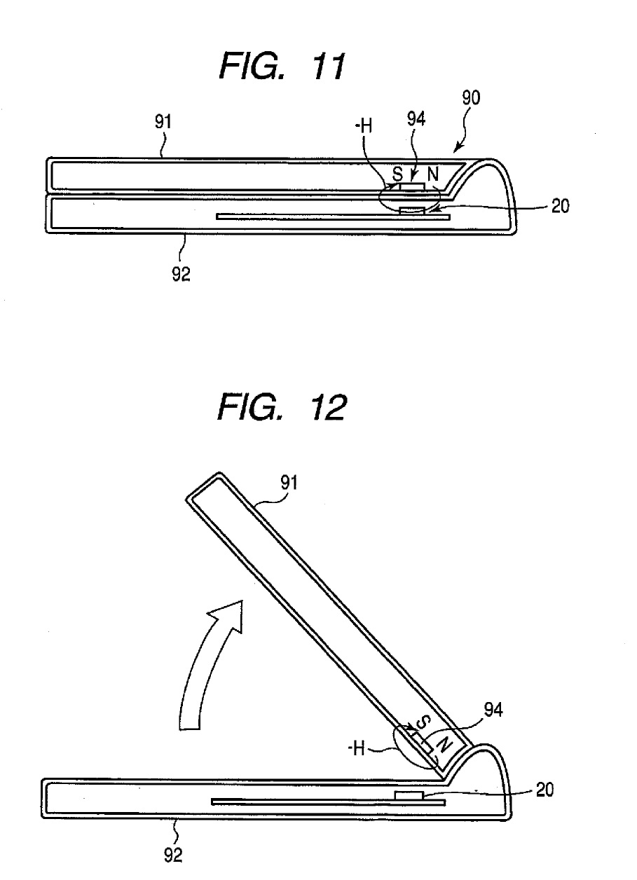

The magnetic detection device 20 of the embodiment is the NS detection sensor. That is, an N pole of the magnet 94 is disposed on the left side of the illustration portion of the magnet and an S pole is disposed on the right side of the illustration portion in FIG. 9. On the contrary, when the polarity is inversely disposed as shown in FIG. 11, for example the N pole is right side and the S pole is left side, the external magnetic field (−H) direction acting on the magnetic detection device 20 (hereinafter, it will be referred to as the negative direction) and the external magnetic field (+H) in FIG. 1 are reversed with each other. In the embodiment, the open operation of the foldable cellular phone can be properly detected when the closing state of the cellular phone 90 in FIG. 11 is changed into the opening state in FIG. 12.

Accordingly, there is no limitation to dispose the magnet 94 irrespective of the polarity of the external magnetic field, and thus it is easy to assemble the foldable cellular phone.

In the aforementioned detection method about opening and closing of the foldable cellular phone, the magnetic detection device need not detect the direction of the external magnetic field, but detect just the variation of the external magnetic field in the dipole. In particular, it is possible to configure the device by using any one of the external output terminals 40 and 41 shown in FIGS. 1 and 2.

For instance, the second switch circuit 43 is removed in FIGS. 1 and 2, so that one signal line is formed to reach the output terminal 40 through the latch circuit 46 and the FET circuit 54 from the comparator 38. Then the detection signal of the external magnetic field in the positive direction (+H) and the external magnetic field in the negative direction (−H) can be obtained from the external output terminal 40. At this time, since both detection signals are such as the low level signal as above mentioned, the signal can not be distinguished whether it is the positive direction or negative direction of the external magnetic field, but it is not necessary to detect the direction of the external magnetic field in the open and close detection. Therefore, it is possible to form more simply the circuit configuration by using just one external output terminal.

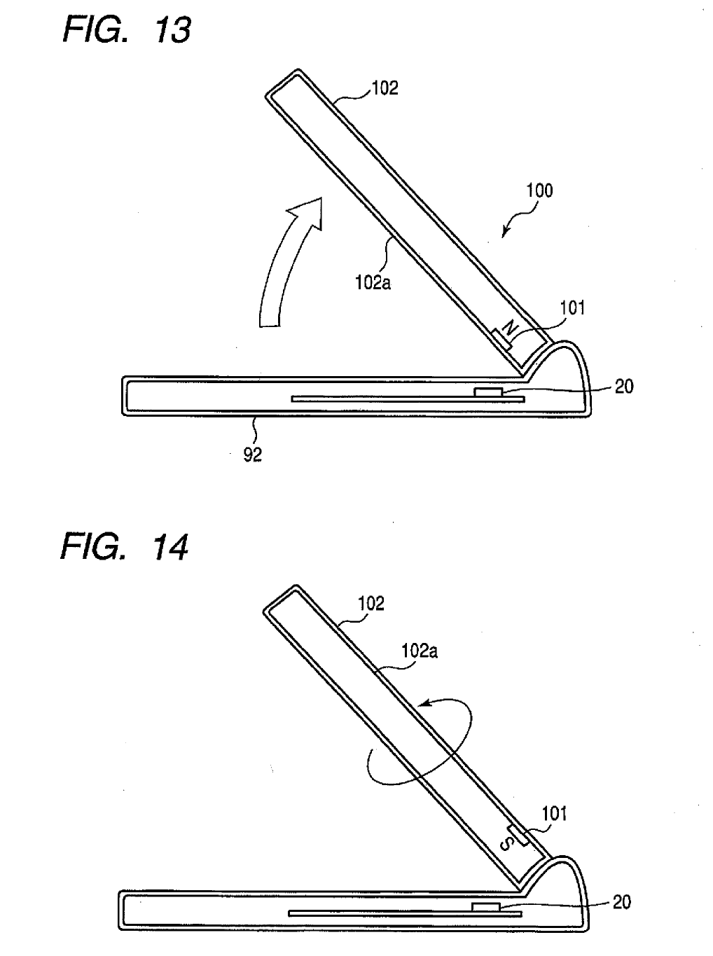

By contrast, when operating variable functions according to the direction of the external magnetic field, such as a turn over type foldable cellular phone 100 in FIGS. 13 and 14 as will be described below, it is recommended to configure the magnetic detection device being detectable even in the direction of the external magnetic field by forming both external output terminals 40 and 41 as shown in FIGS. 1 and 2.

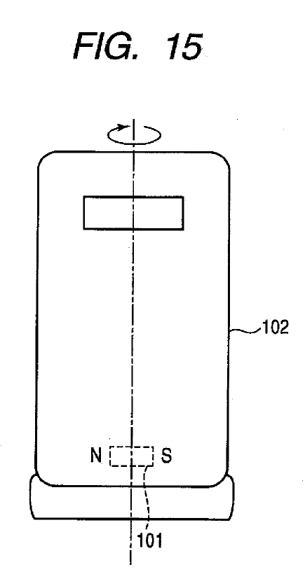

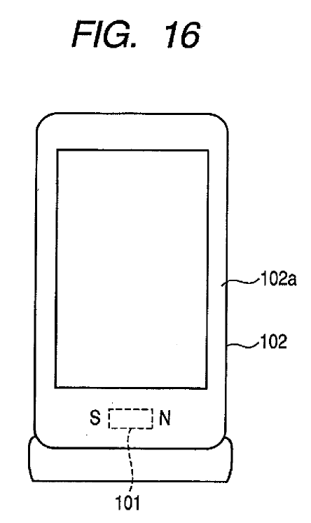

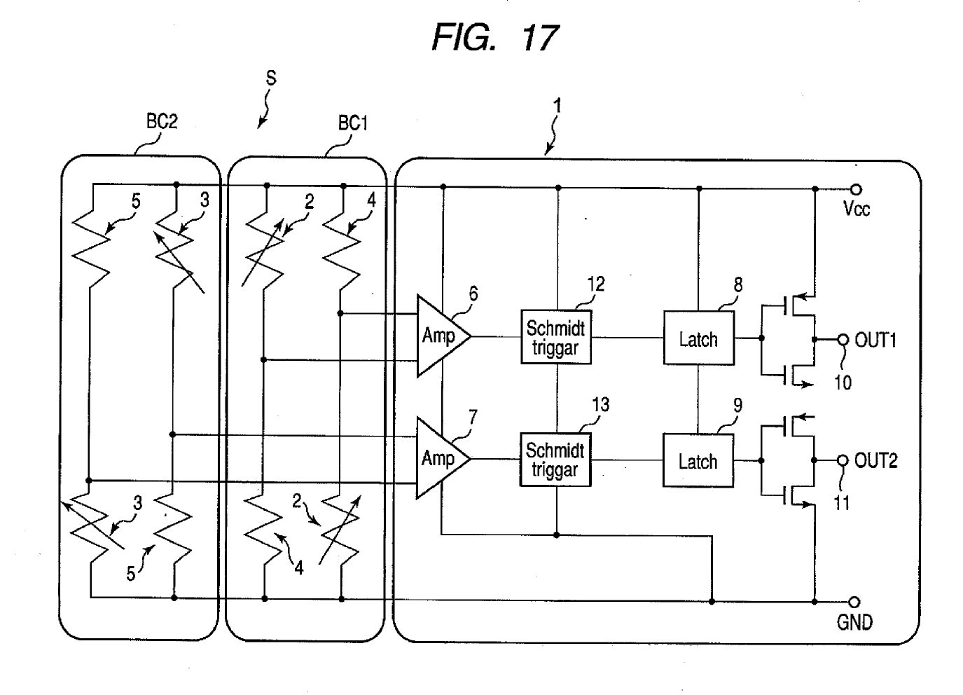

When the foldable cellular phone 100 is opened as shown FIG. 13, the opening state of the foldable cellular phone is detected according to the magnitude variation of the external magnetic field acting on the magnetic detection device 20 as illustrated in FIG. 10 and FIG. 12. An arrangement of a magnet 101 in FIG. 13 is the same as a top view in FIG. 15, the first member 102 of the foldable cellular phone 100 is rotated by 180 degrees about a rotation axis, so that the screen display surface 102a located on an inside of the first member in die state of FIG. 13 is set to face outside as shown in FIGS. 14 and 16. Accordingly, the direction of the magnet 101 is reversed from a state shown in FIG. 15 as shown in FIG. 16. For example, when a camera function is operated by turning over the first member 102, the magnetic detection device 20 should detect the reversing state of the direction of the magnet 101 other than the open and close detection function of the cellular phone 100 as shown in FIG. 13. However, the magnetic detection device 20 of the embodiment can detect whether it is the external magnetic field in the positive direction (+H) or the external magnetic field in the negative direction (−H) in accordance with the circuit configuration having two output terminals 40 and 41 as shown in FIGS. 1 and 2.

In the embodiment, the element configuration of the sensor unit 21 is only one example. For example, the second resistance element 24 connected to the first series circuit 26 and the sixth resistance element 28 connected to the third series circuit 30 as shown in FIGS. 1 and 2 are the fixed resistance elements such as an invariable resistance in response to the external magnetic field. In contrast, the second resistance element 24 has variable electrical resistance with the external magnetic field in the positive direction (+H), but the second resistance element 24 is formed of the magneto-resistance element which has an inverse pattern compared with the first magneto-resistance element 23 in increase and decrease of the resistance corresponding to the magnitude variation of the external magnetic field. The sixth resistance element 28 has variable electrical resistance in response to the external magnetic field in the negative direction (−H), but the second resistance element 24 is formed of the magneto-resistance element which have inverse pattern compared with the second magneto-resistance element 27 in increase and decrease of the resistance corresponding to the intensity variation of the external magnetic field. Consequently, it is preferable that the differential potential can be increased and the detection sensitivity can be enhanced.

Moreover, it is selectable whether or not to apply a bias magnetic field on the magneto-resistance element. It is not necessary to apply the bias magnetic field to the tree magnetic layer included in the magneto-resistance element. On the contrary, when the bias magnetic field is applied, for example, the magnetization of the fixed magnetic layer and the free magnetic layer is controlled so as to be orthogonal each other in state where the external magnetic field does not exist

Furthermore, the magnetic detection device 20 may be available for the use of the open and close detection of electronic devices such as a game device and the like, other than the opening and closing detection of the foldable cellular phone. The embodiment is also available for not only the use of the open and close detection mentioned above, but also the use required for the magnetic detection device 20 of the dipole detection correspondence.

What is claimed is:

1. A magnetic detection device comprising:
a bridge circuit including a first series circuit connected to a second series circuit in a parallel connection,
wherein at least one of a plurality of resistance elements included in the first series circuit include magneto-resistance elements using a magneto-resistance effect, of which an electric resistance varies with an external magnetic field;
wherein a plurality of resistance elements included in the second series circuit include a fixed resistance element of which an electric resistance does not vary with the external magnetic field, and
wherein an element resistance of the fixed resistance elements included in the second series circuit is larger than that of the element resistance of the resistance element included in the first series circuit.

2. The magnetic detection device according to claim 1, further comprising a sensor unit including the first series circuit and an integrated circuit connected to the sensor unit so as to output a magnetic field detection signal, disposed on a substrate,
wherein the second series circuit is incorporated in the integrated circuit.

3. The magnetic detection device according to claim 1, further comprising a third series circuit,
wherein the magneto-resistance element provided in the first series circuit uses a magneto-resistance effect, where an electric resistance varies with a variation in magnitude of an external magnetic field of one direction;
wherein at least one of a plurality of the resistance elements included in the third series circuit include a magneto-resistance element of which an electric resistance varies with an external magnetic field of the direction opposite to the one direction, and
wherein a first bridge circuit is operable to detect the external magnetic field of the one direction is formed by connecting the first series circuit to the second series circuit in parallel, and a second bridge circuit for detecting the external magnetic field of the opposite direction formed by connecting the second series circuit to the third series circuit in parallel.

4. The magnetic detection device according to claim 3, wherein a plurality of resistance elements included in the third series circuit are formed of the same material layer.

5. The magnetic detection device according to claim 3, further comprising a sensor unit including the first series circuit and the integrated circuit connected to the sensor unit so as to output a magnetic field detection signal, disposed on a substrate,
wherein the second series circuit is fitted into the integrated circuit.

6. The magnetic detection device according to claim 2, wherein the integrated circuit is formed on the substrate, and the sensor unit is formed on the integrated circuit with an insulating layer interposed therebetween.

7. The magnetic detection device according to claim 1, wherein a plurality of resistance elements included in the first series circuit are formed of the same material layer.

8. The magnetic detection device according to claim 1, wherein a plurality of fixed resistance elements included in the second series circuit include the same material layer.

9. The magnetic detection device according to claim 8, wherein the fixed resistance element includes silicon.
